(19) United States
(12) Patent Application Publication
(10) Pub. No.: US 2023/0369827 A1
(43) Pub. Date: Nov. 16, 2023

(54) OPTOELECTRONIC SEMICONDUCTOR COMPONENT, AND METHOD FOR PRODUCING AN OPTOELECTRONIC SEMICONDUCTOR COMPONENT

(71) Applicant: ams-OSRAM International GmbH, Regensburg (DE)

(72) Inventors: Alexander Behres, Pfatter (DE); Christian Lauer, Pettendorf (DE); Martin Hetzl, Painten (DE)

(73) Assignee: ams-OSRAM International GmbH, Regensburg (DE)

(21) Appl. No.: 18/245,071

(22) PCT Filed: Sep. 3, 2021
(86) PCT No.: PCT/EP2021/074389

§ 371 Date: Mar. 13, 2023

(30) Foreign Application Priority Data
Sep. 14, 2020 (DE) 102020123854.1

(51) Int. Cl. H01S 5/22

(52) U.S. Cl. CPC H01S 5/2215

(57) ABSTRACT

An optoelectronic semiconductor component is specified, including at least one layer stack having - an active zone for generating electromagnetic radiation, - at least one aluminum-containing current constriction layer including a first region and a second region, the second region having a lower electrical conductivity than the first region, and - a side surface which laterally delimits the layer stack and at which the second region is arranged, the second region being an oxidized region. A method for producing an optoelectronic semiconductor component is furthermore specified.

### CROSS-REFERENCE TO RELATED APPLICATIONS

The present application is a national stage entry from International Application No. PCT/EP2021/074389, filed on Sep. 3, 2021, published as International Publication No. WO 2022/053406 A1 on Mar. 17, 2022, and claims priority to German Application 10 2020 123 854.1 filed Sep. 14, 2020, the disclosures of all of which are hereby incorporated by reference herein in their entireties.

### FIELD

An optoelectronic semiconductor component and a method for producing the same are specified. In particular, the optoelectronic semiconductor component is an edge-emitting laser component.

### BACKGROUND

In the case of edge-emitting laser diodes, it is a known problem that strong heating and degradation can occur at a mirror facet intended for radiation outcoupling due to very high optical power densities. Above a certain power threshold, COMD (Catastrophic Optical Mirror Damage) occurs, leading to a sudden failure of the component. This problem can be countered by reducing the current flow to the mirror facet. However, previous approaches are limited in that the current flow to the mirror facet can only be reduced on a side of an active zone of the laser diode facing away from the substrate. For example, a current can be laterally constricted by retracting a contact layer facing away from the substrate from the mirror facet.

It is an object of the present disclosure to specify a robust optoelectronic semiconductor component that is relatively easy to manufacture. Another object to be achieved is to specify a relatively simple method for producing a robust optoelectronic semiconductor component.

These objects are achieved, inter alia, by an optoelectronic semiconductor component and a method for producing an optoelectronic semiconductor component having the features of the independent claims.

### SUMMARY

According to at least one embodiment of an optoelectronic semiconductor component, the optoelectronic semiconductor component comprises at least one layer stack comprising an active zone for generating electromagnetic radiation and at least one aluminum-containing current constriction layer comprising a first region and a second region, the second region having a lower electrical conductivity than the first region. Further, the layer stack has a side surface which laterally delimits the layer stack and at which the second region is arranged, the second region being an oxidized region. By means of the current constriction layer, the current flow to the side surface can be reduced and the current can be laterally constricted. Advantageously, the second region reduces the current flow in the region of the side surface, thereby increasing the stress limit of the semiconductor component.

In the present disclosure, the term “oxidized region” refers in particular to a region of an originally non-oxidized aluminum-containing current constriction layer or starting layer produced by oxidation. Oxidation can still take place after the layer stack has been produced.

Preferably, the starting layer is a high-aluminum AlGaInAsP layer with an aluminum content of at least 90%. Preferred values are 90%, 95%, 98%, 99% and 100%. In other words, the starting layer is formed of AlxGayIn1-x-yAsP, where 0.9 ≤ x ≤ 1 and x + y ≤ 1. Here, the indium and/or phosphorus content in the layer can vary, for example, to optimize band progressions and strains. Furthermore, the aluminum content can vary within the specified value range in the layer, for example by alloy ramps or a stack with different compositions. This allows, for example, an electrical series resistance and optical mode guiding to be optimized.

Further preferably, the first region is a non-oxidized region of the starting layer, so that its material composition corresponds in particular to that of the starting layer. Accordingly, the first region preferably contains or consists of AlxGayIn1-x-yAsP, where 0.9 ≤ x ≤ 1 and x + y ≤ 1. Furthermore, the second region in particular has a higher oxygen content than the first region.

In the present disclosure, “lateral” refers in particular to a direction running parallel to a main extension plane of the layer stack. In particular, the current constriction layer is arranged substantially parallel to the main extension plane. Furthermore, the first and second regions are preferably arranged side by side, that is, laterally non-overlapping for the most part, the first region being arranged on a side of the second region facing away from the side surface.

According to at least one embodiment, the second region has a lateral extent between 0.1 µm and 100 µm inclusive. Preferred values are 0.1 µm, 1 µm, 5 µm, 10 µm, 15 µm, 20 µm, 25 µm, 50 µm and 100 µm.

According to at least one embodiment, the layer stack comprises at least one n-type semiconductor layer and at least one p-type semiconductor layer, the active zone being arranged between the at least one n-type semiconductor layer and the at least one p-type semiconductor layer. The direction in which the n-type semiconductor layer, the active zone and the p-type semiconductor layer succeed each other is hereinafter referred to as the “vertical direction,” which is perpendicular to the lateral direction.

The at least one n-type semiconductor layer, the active zone and the at least one p-type semiconductor layer are, in particular, epitaxially grown layers on a substrate, wherein the substrate can remain in the finished semiconductor component or be removed and replaced by another carrier. Preferably, the current constriction layer is also an epitaxially grown layer. Advantageously, the current constriction layer can be integrated into the layer stack on a side of the active zone facing the substrate and/or facing away from the substrate. Thus, the current constriction layer may be located at different vertical positions in the layer stack. For example, the side of the active zone of the layer stack facing the substrate is the n-side, and the side of the active zone of the layer stack facing away from the substrate is the p-side of the layer stack. Alternatively, the side of the active zone facing the substrate may be the p-side, and the side of the active zone facing away from the substrate may be the n-side of the layer stack.

The active zone contains, for example, a sequence of individual layers by means of which a quantum well structure, in particular a single quantum well structure (SQW) or multiple quantum well structure (MQW), is formed.

Materials based on phosphide and/or arsenide compound semiconductors are preferably considered for the semiconductor layers of the layer stack. “Based on phosphide or arsenide compound semiconductors” means in the present context that the semiconductor layers contain AlₙGaₘIn₁₋ₙ₋ₘP or AlₙGaₘIn₁₋ₙ₋ₘAs, where 0 ≤ n ≤ 1, 0 ≤ m ≤ 1 and n+m ≤ 1. This material does not necessarily have to have a mathematically exact composition according to the above formula. Rather, it may include one or more dopants as well as additional constituents that do not substantially change the characteristic physical properties of the AlₙGaₘIn₁₋ₙ₋ₘP or AlₙGaₘIn₁₋ₙ₋ₘAs material. However, for the sake of simplicity, the above formula includes only the essential constituents of the crystal lattice (Al, Ga, In, P, and As, respectively), even though these may be partially replaced by small amounts of additional substances.

Depending on the position of the current constriction layer, i.e. whether it is located in the n-type region or p-type region of the layer stack, it can be n-doped or p-doped. Suitable dopants include Te, Si, Ge, S, C, Be, Mg, Zn and Se.

According to at least one embodiment, the optoelectronic semiconductor component is an edge-emitting laser component, and the side surface is provided for coupling out the electromagnetic radiation.

The electromagnetic radiation has a coherent portion. For example, the semiconductor component, preferably the layer stack, contains a resonator for this purpose, with the side surface or laser facet forming part of the resonator. In particular, the coherent portion of the electromagnetic radiation is laser radiation, for example infrared or visible laser radiation. The coherent portion may be, for example, laser radiation in the fundamental mode of the resonator.

According to at least one embodiment, the at least one layer stack has a first main surface and a second main surface, which are each arranged transversely to the side surface and, in particular, parallel to the main extension plane and vertically delimit the layer stack, the current constriction layer being arranged closer to the active zone than to the first and/or second main surface. In particular, the current constriction layer is arranged so close to the active zone that hardly any expansion of the laterally constricted current can take place in an intermediate region between the current constriction layer and the active zone. In addition, the current constriction layer is advantageously arranged at a distance from the active zone so that as little additional strains as possible are caused in the active zone by the current constriction layer.

The current constriction layer can have a vertical extent between 2 nm and 200 nm inclusive. Preferred values are 2 nm, 5 nm, 10 nm, 20 nm, 35 nm, 50 nm, 100 nm, 200 nm.

According to at least one embodiment, the layer stack comprises at least two aluminum-containing current constriction layers that differ from each other in their material composition and/or vertical extent and/or lateral extent of the second regions. For example, the different material compositions of the current constriction layers may be selected such that faster and thus laterally deeper penetrating oxidation occurs in the starting layer of one current constriction layer than in the starting layer of the other current constriction layer. In particular, the aluminum content of the current constriction layers with different material compositions differs. Further, it is possible that the different vertical extents or thicknesses of the starting layers are selected such that faster and thus laterally deeper penetrating oxidation occurs in one starting layer than in the other starting layer. In particular, the thicker current constriction layer has a greater lateral extent of the second region than the thinner current constriction layer.

Furthermore, the current constriction layers are preferably arranged at different vertical positions of the layer stack. For example, the current constriction layers may be arranged on different sides of the active zone. Furthermore, it is possible that at least two current constriction layers with different lateral extents of the second regions are directly adjacent to each other, whereby a desired current profile can be adjusted.

According to at least one embodiment, the optoelectronic semiconductor component comprises at least two layer stacks of the type mentioned above, which are arranged one above the other, with a tunnel junction being arranged between the layer stacks. The tunnel junction comprises, in particular, two highly doped layers of different conductivity types (n-type and p-type, respectively) and serves to electrically connect the layer stacks. In particular, the layer stacks are electrically connected in series by the tunnel junction. The tunnel junction forms particularly low potential barriers, which facilitates the tunneling of charge carriers between the active zones arranged one above the other. The tunneling generates charge carrier pairs necessary for the current flow between the two layer stacks.

Furthermore, the active zones of the layer stacks emit radiation in the same wavelength range in particular, so that the optical output power of the semiconductor component can be increased by the plurality of layer stacks.

According to at least one embodiment, the current constriction layer or several current constriction layers are arranged in the region of at least one of the following elements of the optoelectronic semiconductor component: p-contact layer, p-cladding layer, p-waveguide, active zone, n-contact layer, n-cladding layer, n-waveguide, buffer layer, nucleation layer, tunnel junction. As already mentioned above, the current constriction layer is advantageously arranged, on the one hand, so close to the active zone that hardly any expansion of the laterally constricted current can occur in an intermediate region between the current constriction layer and the active zone, and, on the other hand, so far away from the active zone that as little additional strains as possible caused by the current constriction layer occur there.

The method described below is suitable for producing an optoelectronic semiconductor component or a plurality of optoelectronic semiconductor components of the type mentioned above. Features described in connection with the semiconductor component can therefore also be used for the method and vice versa.

According to at least one embodiment of a method for producing an optoelectronic semiconductor component of the type mentioned above, the method comprises the following steps carried out in succession:
Providing at least one layer stack comprising at least one aluminum-containing starting layer and a side surface laterally delimiting the layer stack,
forming a current constriction layer comprising a first region and a second region which is arranged at the side surface and has a lower electrical conductivity than the first region by oxidizing the at least one aluminum-containing starting layer in the second region.

Preferably, the oxidation process already takes place at wafer level after the side surfaces of the layer stacks have been exposed or after facet breaking, the wafer comprising a large number of layer stacks which are arranged in a composite.

According to a preferred embodiment of the method, the second region is generated by means of lateral oxidation of the starting layer starting from the side surface. The lateral penetration depth or lateral extent of the second region is between 0.1 µm and 100 µm inclusive.

There are various ways of regulating the penetration depth of the oxidation. For example, the penetration depth can be regulated by the vertical extent of the current constriction layer. In particular, a thicker starting layer exhibits faster, deeper oxidation than a thinner starting layer.

Furthermore, the penetration depth of the oxidation can be regulated by the aluminum content of the starting layer. In particular, a higher aluminum content leads to faster, deeper oxidation.

Also, the penetration depth of the oxidation can be regulated by a duration of the oxidation process. In particular, a longer oxidation process leads to deeper oxidation.

The optoelectronic semiconductor component is particularly suitable for semiconductor laser applications in the automotive and multimedia sectors.

Further advantages, advantageous embodiments and further developments will become apparent from the exemplary embodiments described below in connection with the figures.

### BRIEF DESCRIPTION OF THE DRAWINGS

In the figures:

FIGS. 1A and 1C each show a schematic cross-sectional view of a right edge region of an optoelectronic semiconductor component according to a first and a second exemplary embodiment, wherein the current constriction layer is arranged in the region of a waveguide, and FIGS. 1A and 1B show a method for producing an optoelectronic semiconductor component according to the first exemplary embodiment,

FIGS. 2A and 2B each show a schematic cross-sectional view of a right edge region of an optoelectronic semiconductor component according to a third and a fourth exemplary embodiment, wherein the current constriction layer is arranged in the region of a cladding layer,

FIGS. 3A and 3B each show a schematic cross-sectional view of a right edge region of an optoelectronic semiconductor component according to a fifth and a sixth exemplary embodiment, wherein the current constriction layer is arranged in the region of the active zone,

FIG. 4 shows a schematic cross-sectional view of a right edge region of an optoelectronic semiconductor component according to a seventh exemplary embodiment, wherein the current constriction layer is arranged in the region of a contact layer,

FIG. 5 shows a schematic cross-sectional view of a right edge region of an optoelectronic semiconductor component according to an eighth exemplary embodiment, wherein the current constriction layer is arranged in the region of a buffer layer,

FIG. 6 shows a schematic cross-sectional view of a right edge region of an optoelectronic semiconductor component according to a ninth exemplary embodiment, which has current constriction layers in the region of the waveguides,

FIG. 7 shows a schematic cross-sectional view of a right edge region of an optoelectronic semiconductor component according to a tenth exemplary embodiment, which has current constriction layers in the region of the cladding layers,

FIG. 8 shows a schematic cross-sectional view of a right edge region of an optoelectronic semiconductor component according to an eleventh exemplary embodiment, which has current constriction layers in the region of the active zone,

FIG. 9 shows a schematic cross-sectional view of a right edge region of an optoelectronic semiconductor component according to a twelfth exemplary embodiment, which has current constriction layers in the region of the contact layer and the buffer layer,

FIG. 10 shows a schematic cross-sectional view of a right edge region of an optoelectronic semiconductor component according to a thirteenth exemplary embodiment, which has current constriction layers comprising second regions of different vertical and lateral extents,

FIG. 11 shows a schematic cross-sectional view of a right edge region of an optoelectronic semiconductor component according to a fourteenth exemplary embodiment, which has current constriction layers of different material compositions and oxidation depths,

FIG. 12 shows a schematic cross-sectional view of an optoelectronic semiconductor component according to a fifteenth exemplary embodiment, which has adjacent current constriction layers comprising second regions of different lateral extents,

FIG. 13 shows a schematic cross-sectional view of an optoelectronic semiconductor component according to a sixteenth exemplary embodiment, which has current constriction layers in the region of a tunnel junction.

### DETAILED DESCRIPTION

In the exemplary embodiments and figures, identical elements, elements of the same kind or elements having the same effect may each be provided with the same reference signs. The elements shown and their proportions to one another are not necessarily to be regarded as true to scale; rather, individual elements may be shown exaggeratedly large for better representability and/or better understanding.

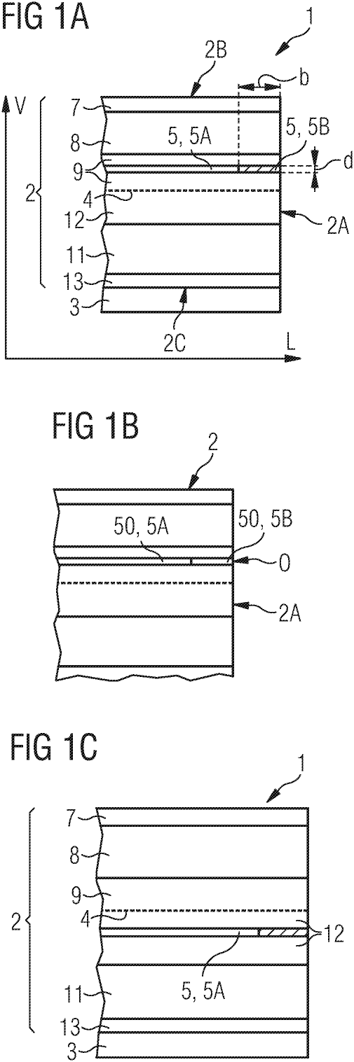

FIG. 1A shows a first exemplary embodiment of an optoelectronic semiconductor component 1 in a cross-sectional view, wherein a cross-sectional plane is arranged perpendicular to a side surface 2A and a first main surface 2B and second main surface 2C of a layer stack 2 of the semiconductor component 1. In particular, the optoelectronic semiconductor component 1 is an edge-emitting laser component in which electromagnetic radiation is coupled out of the optoelectronic semiconductor component 1 through the side surface 2A in a lateral direction L.

The optoelectronic semiconductor component 1 includes the layer stack 2 and a substrate 3 on which the layer stack 2 is arranged. The substrate 3 may be a growth substrate on which the layer stack 2 is epitaxially grown or a replacement substrate which replaces the original growth substrate.

The layer stack 2 comprises a plurality of n-side, at least partially n-conductive layers 13, 11, 12 and a plurality of p-side, at least partially p-conductive layers 9, 8, 7, which follow each other in the vertical direction V. Furthermore, the layer stack 2 has an active zone 4 arranged between the n-side layers 11, 12, 13 and the p-side layers 7, 8, 9. In particular, layer 7 is a p-contact layer, layer 8 is a p-cladding layer, layer 9 is a p-waveguide, layer 12 is an n-waveguide, layer 11 is an n-cladding layer, and layer 13 is a buffer layer. The layer stack 2 may have further layers (not shown) between the aforementioned layers 7, 8, 9, 11, 12, 13.

Furthermore, the active zone 4 can contain a sequence of individual layers by means of which a quantum well structure, in particular a single quantum well (SQW) or multiple quantum well (MQW) structure, is formed.

Furthermore, both the p-waveguide 9 and the n-waveguide 12 may each have a sequence of individual layers preferably with alternating refractive indices.

For the layer stack 2 or the semiconductor layers 4, 7, 8, 9, 11, 12, 13 contained therein, materials based on phosphide and/or arsenide compound semiconductors, which have been described in more detail above, are preferably considered.

Further, the layer stack 2 comprises an aluminum-containing current constriction layer 5 comprising a first region 5A and a second region 5B, wherein the second region 5B has a lower electrical conductivity than the first region 5A and is an oxidized region.

The oxidized region 5B is generated by oxidation O of an originally non-oxidized aluminum-containing current constriction layer or starting layer 50 (cf. FIG. 1B). By oxidation O of the starting layer 50, i.e. by increasing the oxygen content, in the second region 5B, the electrical conductivity in the second region 5B is reduced. By means of the current constriction layer 5, a current in the semiconductor component 1 can thus be laterally constricted to the first region 5A.

The starting layer 50 is advantageously a high-aluminum AlGaInAsP layer with an aluminum content of at least 90%. Preferred values are 90%, 95%, 98%, 99% and 100%. In other words, the starting layer is formed of AlxGayIn1-x-yAsP, where 0.9 ≤ x ≤ 1 and x + y ≤ 1. Furthermore, the first region 5A is a non-oxidized region of the starting layer 50, so that its material composition corresponds in particular to that of the starting layer. Accordingly, the first region 5A preferably contains or consists of AlxGayIn1-x-yAsP, where 0.9 ≤ x ≤ 1 and x + y ≤ 1.

The second, oxidized region 5B is arranged at the side surface 2A and can thus reduce a current flow directed toward the side surface 2A. This protects the side surface 2A, which is in particular a mirror facet, from excessive heating and degradation and enables an increase of the optical output power, since this is often limited by the degradation of the mirror facet.

In the first exemplary embodiment, the current constriction layer 5 is arranged in the p-waveguide 9. The current constriction layer 5 is thus arranged so close to the active zone 4 that hardly any expansion of the laterally constricted current can occur in an intermediate region between the current constriction layer 5 and the active zone 4.

The second region 5B has a lateral extent b between 0.1 µm and 100 µm inclusive, with preferred values being 0.1 µm, 1 µm, 5 µm, 10 µm, 15 µm, 20 µm, 25 µm, 50 µm, and 100 µm.

Furthermore, the current constriction layer 5 may have a vertical extent d between 2 nm and 200 nm inclusive, with preferred values being 2 nm, 5 nm, 10 nm, 20 nm, 35 nm, 50 nm, 100 nm, 200 nm.

Referring to FIGS. 1A and 1B, a method for producing the optoelectronic semiconductor component 1 is explained in more detail. First, a layer stack 2 is provided having an aluminum-containing starting layer 50 and a side surface 2A laterally delimiting the layer stack 2. Then, a current constriction layer 5 having a first region 5A and a second region 5B arranged at the side surface 2A and having a lower electrical conductivity than the first region 5A is formed by oxidizing the aluminum-containing starting layer 50 in the second region 5B.

In particular, the oxidized region 5B is generated by means of lateral oxidation O of the starting layer 50 starting from the side surface 2A.

FIG. 1C shows a second exemplary embodiment of an optoelectronic semiconductor component 1. While the current constriction layer 5 is arranged on the p-side in the first exemplary embodiment, it is located on the n-side of the layer stack 2 in the n-waveguide 12 in the second exemplary embodiment. Compared to previous structures in which the current to the mirror facet can only be constricted on a side of the active zone of the laser diode facing away from the substrate, in the second exemplary embodiment the current constriction takes place on the n-side facing the substrate 3.

FIG. 2A shows a third exemplary embodiment of an optoelectronic semiconductor component 1. While the current constriction layer 5 is arranged in the p-waveguide 9 in the first exemplary embodiment, it is located in the p-cladding layer 8 in the third exemplary embodiment. Thus, the current constriction layer 5 is arranged further away from the active zone 4, so that additional strains caused by the current constriction layer 5 can be reduced.

FIG. 2B shows a fourth exemplary embodiment of an optoelectronic semiconductor component 1, in which the current constriction layer 5 is arranged in the n-cladding layer 11 and thus on the side of the layer stack 2 facing the substrate.

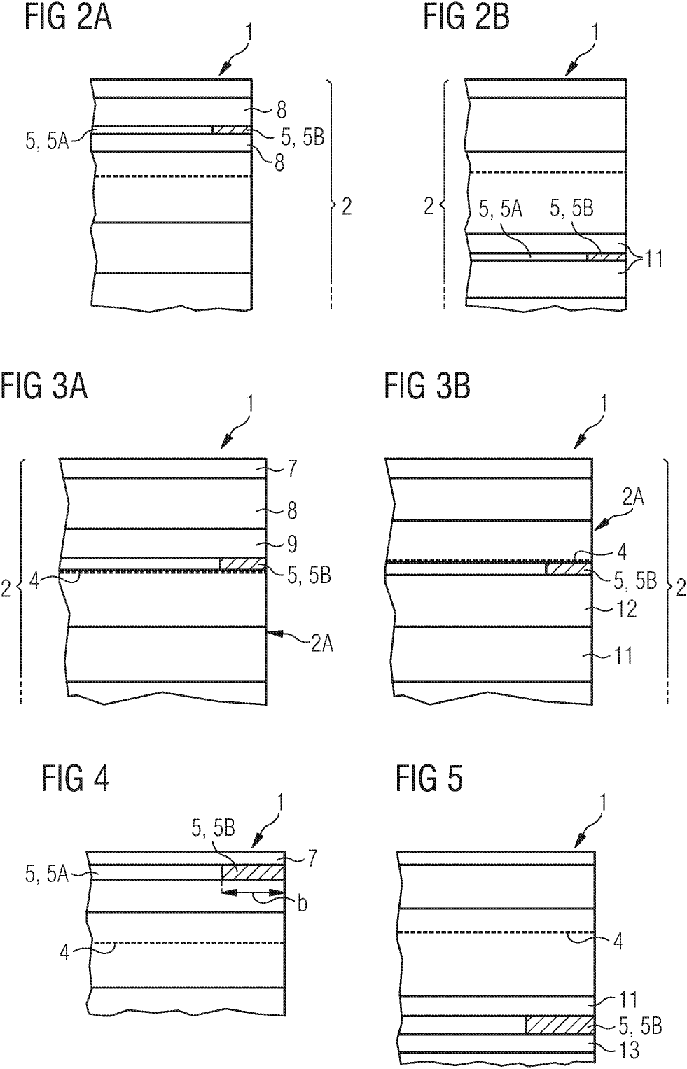

FIGS. 3A and 3B show a fifth and a sixth exemplary embodiment of an optoelectronic semiconductor component 1, wherein the current constriction layer 5 is arranged in the region of the active zone 4 on the side of the active zone 4 facing away from the substrate (cf. FIG. 3A) or on the side facing the substrate (cf. FIG. 3B). This allows the charge carrier density in the active zone 4 to be reduced in a targeted manner on the side surface 2A.

FIG. 4 shows a seventh exemplary embodiment of an optoelectronic semiconductor component 1. Here, the current constriction layer 5 is located in the region of the p-contact layer 7. Thus, the current constriction layer 5 is arranged even further away from the active zone 4 than in the third exemplary embodiment, so that additional strains caused by the current constriction layer 5 can be further reduced. In order to nevertheless ensure sufficient current constriction in the region of the active zone 4, the second region 5B can, for example, be formed with a larger lateral extent b than in the first exemplary embodiment.

FIG. 5 shows an eighth exemplary embodiment of an optoelectronic semiconductor component 1, in which the current constriction layer 5 is arranged in the region of the buffer layer 13 and thus on the side of the layer stack 2 facing the substrate. The current constriction layer 5 is arranged further away from the active zone 4 than in the fourth exemplary embodiment, so that additional strains caused by the current constriction layer 5 can be further reduced.

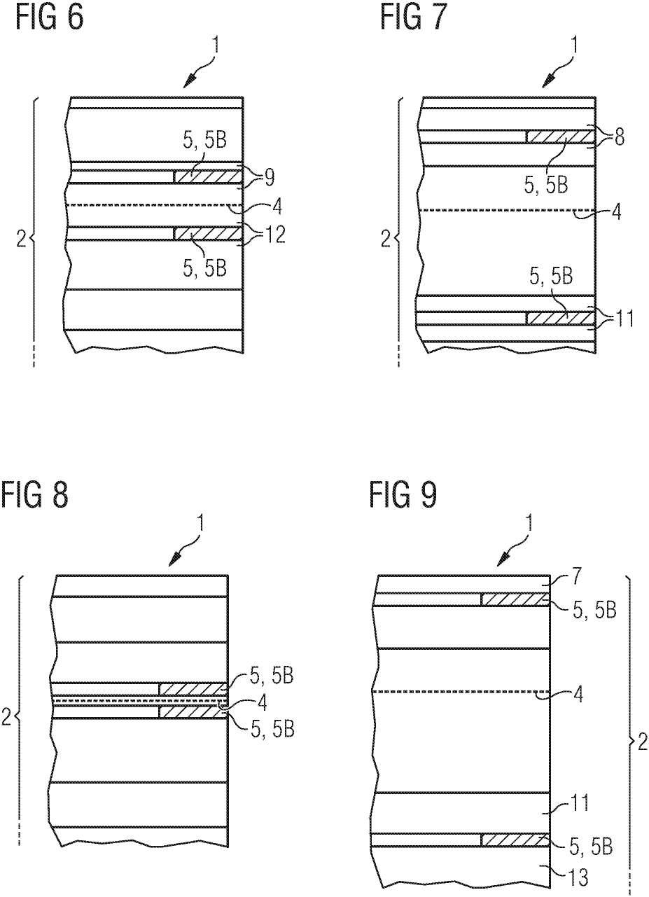

In the exemplary embodiments shown in FIGS. 6 to 9, the layer stacks 2 of the semiconductor components 1 each have a plurality of current constriction layers 5 arranged on the p-side and the n-side, so that current constriction can take place on both sides.

For example, in the ninth exemplary embodiment shown in FIG. 6, the current constriction layers 5 are arranged in the region of the p-waveguide 9 and the n-waveguide 12. This exemplary embodiment also has the advantages mentioned in connection with the first and second exemplary embodiments.

Furthermore, in the tenth exemplary embodiment shown in FIG. 7, the current constriction layers 5 are arranged in the region of the p-cladding layer 8 and the n-cladding layer 11. This exemplary embodiment also has the advantages mentioned in connection with the third and fourth exemplary embodiments.

In the eleventh exemplary embodiment shown in FIG. 8, the current constriction layers 5 are arranged in the region of the active zone 4. This exemplary embodiment also has the advantages mentioned in connection with the fifth and sixth exemplary embodiments.

Furthermore, in the twelfth exemplary embodiment shown in FIG. 9, the current constriction layers 5 are arranged in the region of the contact layer 7 and the buffer layer 13. This exemplary embodiment also has the advantages mentioned in connection with the seventh and eighth exemplary embodiments.

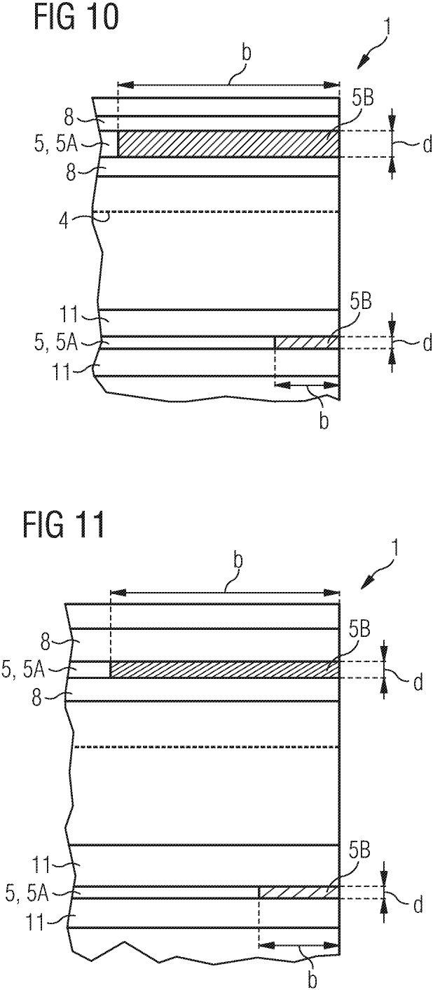

While the current constriction layers 5 in the exemplary embodiments shown in FIGS. 6 to 9 are formed in particular identically in each case, FIGS. 10 and 11 show exemplary embodiments in which the layer stack 2 has two current constriction layers 5 which differ from each other in the lateral extent b of the second regions 5B. This can be achieved in the thirteenth exemplary embodiment shown in FIG. 10 by different vertical extents d of the associated starting layers, with faster and thus laterally deeper penetrating oxidation occurring in the thicker starting layer than in the thinner starting layer.

In the fourteenth exemplary embodiment shown in FIG. 11, the current constriction layers 5 or the starting layers used to produce the current constriction layers 5 differ in their material composition. In this case, the material compositions are selected such that a faster and thus laterally deeper penetrating oxidation occurs in one starting layer than in the other starting layer. In particular, the starting layer in which faster oxidation occurs has a higher aluminum content.

FIG. 12 shows a fifteenth exemplary embodiment of a semiconductor component 1, in which the layer stack 2 has two adjacent current constriction layers 5 whose second regions 5B have different lateral extents b. In this way, a desired current profile can be adjusted in a targeted manner. In this case, the current constriction layer 5, which is arranged further away from the active zone 4, has a second region 5B with a greater lateral extent b. Furthermore, the current constriction layer 5 located closer to the active zone 4 advantageously has a higher doping than the other current constriction layer 5. In particular, an excess current at the transition between the two second regions 5B of the current constriction layers 5 can be mitigated in this way.

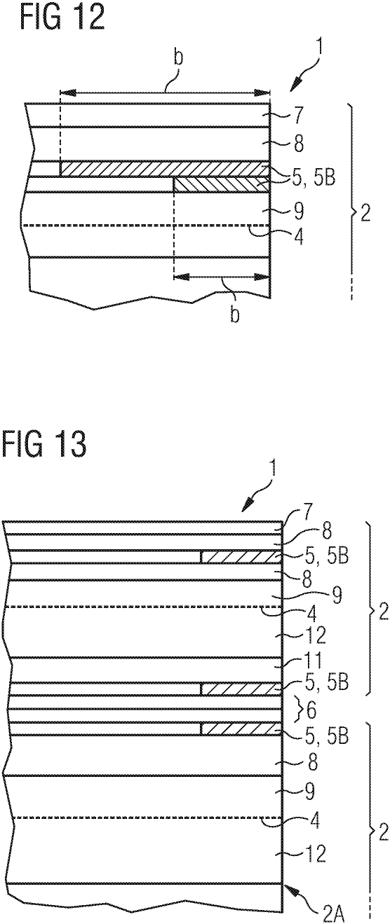

FIG. 13 shows a sixteenth exemplary embodiment of a semiconductor component 1, which has two layer stacks 2 of the above-mentioned type, which are arranged one above the other and in particular are monolithically integrated, a tunnel junction 6 being arranged between the layer stacks 2. The tunnel junction 6 comprises in particular two highly doped layers of different conductivity types (n-type and p-type, respectively) and serves to electrically connect the layer stacks 2. In the region of the tunnel junction 6, the semiconductor component 1 has two current constriction layers 5, which are arranged on opposite sides of the tunnel junction 6. Furthermore, the semiconductor component 1 has a current constriction layer 5 arranged in the cladding layer 8. By means of the layer stacks 2 arranged one above the other, a higher optical output power can be obtained, and the side surface 2A is advantageously protected from excessive heating and degradation by the current constriction layers 5.

In particular, the semiconductor components 1 described in connection with FIGS. 1C to 13 have a structure of the layer stack corresponding to the first exemplary embodiment except for the aforementioned differences.

The invention is not limited by the description based on the exemplary embodiments. Rather, the invention encompasses any new feature as well as any combination of features, which in particular includes any combination of features in the patent claims, even if this feature or combination itself is not explicitly stated in the patent claims or embodiments.

1. An optoelectronic semiconductor component comprising at least one layer stack comprising:
an active zone for generating electromagnetic radiation,
at least two aluminum-containing current constriction layers each comprising a first region and a second region, the second region having a lower electrical conductivity than the first region, and
a side surface which laterally delimits the layer stack and at which the second region is arranged in each case, the second region being an oxidized region in each case, and wherein the current constriction layers differ from each other in their vertical extent and lateral extent of the second regions, the thicker current constriction layer having a greater lateral extent of the second region than the thinner current constriction layer.

2. The optoelectronic semiconductor component according to claim 1, wherein at least one of the first regions includes AlxGayIn1-x-yAsP and wherein 0.9 ≤ x ≤ 1 and x + y ≤ 1.

3. The optoelectronic semiconductor component according to claim 1, wherein the second region has a higher oxygen content than the first region in each case.

4. The optoelectronic semiconductor component according to claim 1, wherein at least one of the second regions has a lateral extent between 0.1 µm and 100 µm inclusive.

5. The optoelectronic semiconductor component according to claim 1, wherein at least one of the current constriction layers has a vertical extent between 2 nm and 200 nm inclusive.

6. The optoelectronic semiconductor component according to claim 1, wherein the at least one layer stack has a first main surface and a second main surface each arranged transversely to the side surface, at least one of the current constriction layers being arranged closer to the active region than to the first and/or second main surface.

7. The optoelectronic semiconductor component according to claim 1, wherein at least two of the aluminum-containing current constriction layers differ from each other in their material composition and/or vertical extent and/or lateral extent of the second regions.

8. The optoelectronic semiconductor component according to claim 1, comprising at least two layer stacks arranged one above the other, a tunnel junction being arranged between the layer stacks.

9. The optoelectronic semiconductor component according to claim 1, wherein the optoelectronic semiconductor component is an edge-emitting laser component and the side surface is provided for coupling out the electromagnetic radiation.

10. The optoelectronic semiconductor component according to claim 1, wherein at least one of the current constriction layers is arranged in the region of at least one of the following elements of the optoelectronic semiconductor component: p-contact layer, p-cladding layer, p-waveguide, active zone, n-contact layer, n-cladding layer, n-waveguide, buffer layer, nucleation layer, tunnel junction.

11. A method for producing an optoelectronic semiconductor component according to claim 1, comprising:
providing at least one layer stack comprising at least two aluminum-containing starting layers and a side surface laterally delimiting the layer stack, and
forming at least two current constriction layers each comprising a first region and each comprising a second region which is arranged at the side surface and has a lower electrical conductivity than the first region by oxidizing each of the at least two aluminum-containing starting layers in the second region, wherein the current constriction layers differ from each other in their vertical extent and lateral extent of the second regions, the thicker current constriction layer having a greater lateral extent of the second region than the thinner current constriction layer.

12. The method according to claim 11, wherein the second region is generated in each case by means of lateral oxidation of the starting layer starting from the side surface.

13. The method according to claim 12, wherein a penetration depth of the oxidation is regulated in each case by a vertical extent of the starting layer.

14. The method according to claim 12, wherein a penetration depth of the oxidation is regulated in each case by the aluminum content of the starting layer.

15. The method according to claim 12, wherein a penetration depth of the oxidation is regulated in each case by a duration of the oxidation process.

16. The optoelectronic semiconductor component according to claim 1, wherein the current constriction layers are arranged on different sides of the active zone.
